(19) United States
(12) Patent Application Publication
(10) Pub. No.: US 2007/0296075 A1
(43) Pub. Date: Dec. 27, 2007

(54) Package Using Selectively Anodized Metal and Manufacturing Method Thereof

(76) Inventors: Young-Se Kwon, Daejeon (KR); Seong Ho Shin, Daegu (KR)

Correspondence Address: GWIPS;PETER T. KWON, P.O. BOX 231630, CENTERVILLE, VA, 20120, US

(21) Appl. No.: 11/667,537

(22) PCT Filed: Jan. 24, 2005
(86) PCT No.: PCT/KR05/00195

§ 371 Date: May 10, 2007

(30) Foreign Application Priority Data
Nov. 29, 2004 (KR) 10-2004-0098769

(51) Int. Cl. H01L 23/28; H01L 23/10

(52) U.S. Cl. 257/706; 438/122; 257/E23.116

(57) ABSTRACT

A package using selectively anodized metal and a manufacturing method thereof are provided. The method includes a patterning step, an anodized metal film forming step, a via hole forming step, and a bump forming step. The pattering step is performed by attaching a masking material to a surface of a metal substrate for integrating semiconductor elements and patterning regions that will not be anodized. The anodized metal film forming step is performed by selectively anodizing the patterned metal substrate and forming a metal oxidation layer having a predetermined thickness. The via hole forming step is performed by forming the via holes in the metal oxidation layer. The bump forming step is performed by forming the bumps for surface-mounting.

### TECHNICAL FIELD

The present invention relates to a method for manufacturing a package using selectively anodized metal, and more particularly, to a package using selectively anodized metal and manufacturing method thereof capable of selectively forming an oxidation metal film by performing an anodizing reaction on a metal substrate widely used for a package material, manufacturing passive elements (inductor, capacitor, resistor, and transmission line, etc.) and a passive circuit necessary for a system construction on a metal oxidation layer having a low insulation loss, and attaching one or more semiconductor elements of a bare chip state to a surface of the metal substrate where the oxidation film is formed by means of a flip-chip bonding or a wire bonding to effectively emit heat.

### BACKGROUND ART

One of important characteristics that should be provided to a package for a semiconductor device is a heat emission performance. Particularly, as trends of high speed and high power in semiconductors are pursued, great efforts are made in processing high heat generation.

FIG. 1 is a cross-sectional view illustrating one embodiment of a semiconductor package for heat emission according to a related art. First, a substrate 71 having a plurality of solder balls (SB) on its lower surface and a metal cap 79 for sealing an upper surface of the substrate 71 using a sealing agent 72 are prepared. At this point, the substrate 71 is made of a printed circuit board (PCB), a ceramic substrate, or a silicon substrate so that the substrate 71 may be applied to semiconductor packages such as a pin grid array (PGA) type, a land grid array (LGA) type, and a ball grid array (BGA) type. After a semiconductor chip 74 is mounted on a die pad 73 of the substrate 71, a bonding pad of the semiconductor chip 74 is electrically connected with an electrode pad of the substrate 71 using a bonding wire 75. At this point, for the bonding, a tape automated bonding (TAB) technology can be applied instead of electrical connection using the bonding wire 75.

Next, if the wire bonding is completed by the above bonding means, an adhesive 76 for sticking a heat spreader 77 to an upper surface of the semiconductor chip 74 is spread. At this point, the adhesive 76 should not influence a surface of the semiconductor chip 74 and appropriately support the heat spreader 77.

The heat spreader 77 of a flat type is mounted on an upper portion of the adhesive 76. At this point, the heat spreader 77 is mounted between the upper surface of the adhesive 76 and a thermal compound 78.

Further, the heat spreader 77 is selected in a group consisting of copper, copper alloy, aluminum, aluminum alloy, steel, stainless steel having high thermal conductivity.

Next, the upper surface of the substrate 71 is sealed with a metal cap 79. The thermal compound 78 is dotted between the heat spreader 77 and the metal cap 79 before the sealing is performed, whereby adhesiveness or thermal diffusion performance is improved.

Therefore, the substrate 71 and the metal cap 79 are sealed with the sealing agent 72. When the sealing agent 72 is hardened, the thermal compound 78 is also hardened. After that, a heat sink (HS) of a fin shape is attached to an upper surface of the metal cap 79 so that high heat emission may be easily performed, whereby manufacturing of a semiconductor package for heat emission is completed.

Though the above-described semiconductor package for heat emission according to the related art can improve heat emission effect more or less through the metal cap, plastic or ceramic substrates having low thermal conductivity are used for the substrates such as a PCB on which the passive elements (inductor, capacitor, resistor, transmission line, etc.), the passive circuit, and the semiconductors are mounted, thus the substrates show low performance in emitting heat transferred to surfaces of the substrates by heat generated from the elements.

### DISCLOSURE OF INVENTION

### Technical Problem

Accordingly, the present invention is directed to a package using selectively anodized metal and a manufacturing method thereof that substantially obviate one or more of the problems due to limitations and disadvantages of the related art.

An object of the present invention is to provide a package using selectively anodized metal and a manufacturing method thereof capable of forming an insulating layer having an excellent insulation property even in a micro/millimeter wave band through selective anodizing, manufacturing passive elements necessary for realizing a system thereon, and forming inter-connection via holes in a metal substrate using a selective anodizing process so that elements may be surface-mounted on a PCB in a BGA or a LGA type.

Another object of the present invention is to provide a package manufacturing method using selectively anodized metal capable of forming an inductor line on a metal oxidation film of a membrane type in order to realize a high quality inductor on a metal substrate.

Still another object of the present invention is to provide a package manufacturing method using selectively anodized metal capable of forming a selective, anodized layer on both sides of the metal substrate to form passive elements or semiconductor elements thereon, or forming solder bumps for surface-mounting.

### Technical Solution

To achieve these and other advantages and in accordance with the purpose of the present invention, as embodied and broadly described, there is provided a package using a selectively anodized metal in a semiconductor package for integrating semiconductor elements and passive elements on a metal substrate and protecting these elements using a metal cover, the package being formed by integrating the passive elements and the semiconductors on an anodized metal film selectively formed on the metal substrate so as to have a predetermined thickness, forming bumps by interconnection via holes for surface-mounting on the anodized metal film of the metal substrate, sticking a metal cover for protecting the passive elements and the semiconductor elements integrated on the metal substrate, to the metal substrate.

In another aspect of the present invention, there is provided a package manufacturing method using selectively anodized metal in a semiconductor package manufacturing method for emitting heat generated from semiconductor elements, the method including the steps of: attaching a masking material on a metal substrate for integrating the semiconductor elements and pattering regions that will not be anodized; selectively anodizing the patterned metal substrate to form a metal oxidation layer having a predetermined thickness; forming via holes; and forming solder bumps for surface-mounting on the metal substrate.

In still another aspect of the present invention, there is provided a package manufacturing method using selectively anodized metal in a method for manufacturing an inductor reducing parasitic capacitance on a metal substrate and reducing a resistance component of an inductor line, the method including the steps of: attaching a masking material to a portion of the metal substrate where the inductor is manufactured and etching a backside of the metal substrate in a predetermined depth; forming an anodized metal film on the metal substrate to electrically isolate the portion where the inductor is manufactured from other metal portions; and removing the masking material attached to the metal substrate and selectively etching a metal layer that will not be anodized to form a lower line of the inductor.

In further another aspect of the present invention, there is provided a package manufacturing method using selectively anodized metal in a method for manufacturing a metal substrate integrating semiconductor elements and passive elements thereon, the method including the steps of: attaching a masking material to both sides of the metal substrate and patterning both the sides; and forming a metal oxidation layer by selectively anodizing both the sides of the metal substrate.

### Advantageous Effects

As described above, a package using selectively anodized metal and a manufacturing method thereof according to the present invention can manufacture passive elements necessary for a system construction on selectively anodized metal and attach semiconductor elements of a bare chip state on the metal substrate by means of a flip-chip bonding or a wire bonding, thereby effectively emitting heat. The package and the manufacturing method can integrate passive elements showing an excellent electrical property even under an ultra-high frequency wave on the selectively anodized metal layer. Further, the present invention incorporates system parts into one package and integrates the passive elements in an inside of the package, thereby accomplishing low manufacturing costs, a small-sizing, and a light-weight of the system.

### DESCRIPTION OF DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a cross-sectional view illustrating one embodiment of a semiconductor package for heat emission according to a related art;

FIG. 2 is a cross-sectional view of a package using selectively anodized metal according to an embodiment of the present invention;

FIG. 3 is a cross-sectional view illustrating a manufacturing of passive elements on a surface of an anodized metal substrate according to an embodiment of the present invention;

FIGS. 4 to 7 are cross-sectional views illustrating a BGA/LGA manufacturing method using an inter-connection via for surface mounting on a metal substrate according to another embodiment of the present invention;

FIGS. 8 to 10 are cross-sectional views illustrating a method for manufacturing an inter-connection via in a metal substrate according to another embodiment of the present invention;

FIGS. 11 to 13 are cross-sectional views illustrating a method for manufacturing an inductor having a high quality coefficient using a metal substrate and an anodizing process according to still another embodiment of the present invention;

FIG. 14 is a plan view of an inductor formed on a metal substrate in FIG. 13; and

FIG. 15 is a cross-sectional view of double-sided metal substrate package manufactured through a package manufacturing process using a selectively anodized metal according to another embodiment of the present invention.

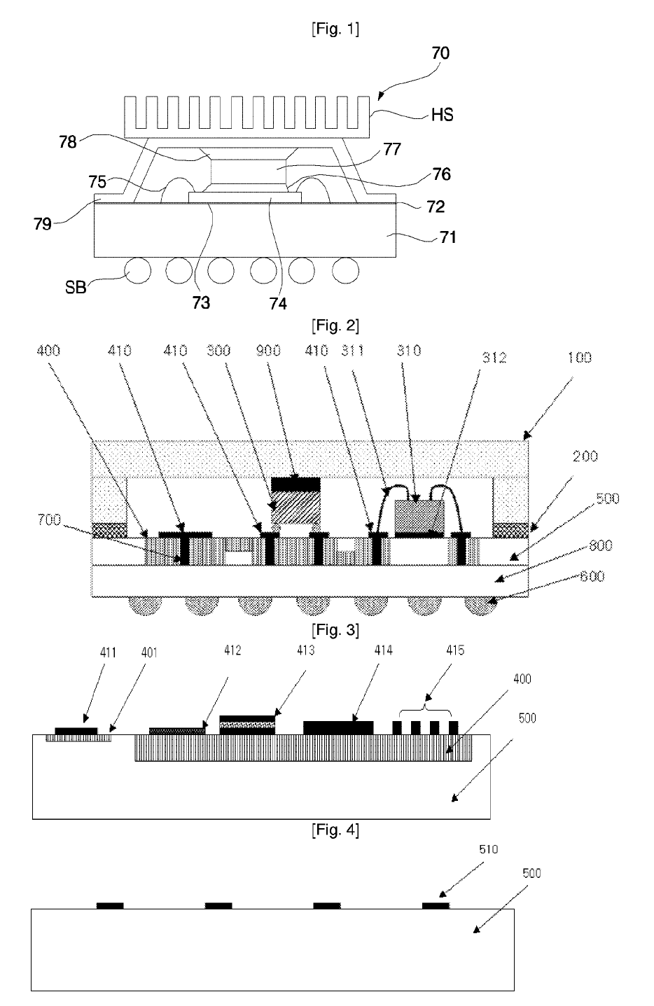

### BEST MODE

Hereinafter, preferred embodiments of the present invention will be described in detail with reference to accompanying drawings.

FIG. 2 is a view illustrating a package using selectively anodized metal according to a first embodiment of the present invention.

Namely, FIG. 2 is a view of the whole construction of a package using metal such as selectively anodized aluminum for a substrate. Referring to FIG. 2, if a thin film such as ‘SiO₂’ or SiNx′ is attached to a metal substrate 500 as a masking material and the metal substrate is anodized, an anodized film 400 having a predetermined thickness can be selectively manufactured on the metal substrate 500.

Passive elements 410 necessary for realizing a system are integrated on the anodized film 400 grown through the above process and semiconductor elements 310 of a bare chip state are connected with the integrated passive elements 410 by means of a flip-chip bonding.

The semiconductor elements 310 may be fixed to a surface of a metal that is not anodized using a thermal conductive adhesive material 312 and may be connected with the passive elements 410 formed on the anodized film by means of a wire bonding 311.

For surface-mounting, BGA or LGA type solder bumps 600 through inter-connection via holes 700 may be formed on the metal substrate 500.

In case the solder bumps 600 are not formed just beneath the via holes 700, a redistribution layer 800 may be formed beneath the metal substrate 500.

For protection of the passive elements 410 and the semiconductor elements integrated on the surface of the selectively anodized metal substrate 500, a metal cover 100 is connected with the selectively anodized metal substrate 500 using an adhesive layer 200 that uses a conductive epoxy or metal-to-metal bonding.

If the metal cover 100 is connected with the semiconductor elements 300 using a thermal conductive adhesive material 900, thermal emission characteristics are improved. Here, for protection of the above elements 300 and 310, a plastic molding may be used instead of the metal cover 100 and the adhesive layer 200.

FIG. 3 is a cross-sectional view illustrating a manufacturing of passive elements on a surface of an anodized metal substrate according to an embodiment of the present invention.

First, since a metal such as an anodized aluminum has a low insulation loss characteristics even under a micro/millimeter wave band, it is possible to manufacture a passive element of a high quality coefficient.

That is, referring to FIG. 3, for manufacturing a bypass capacitor 411, a metal layer for an electrode is attached to a thin anodized layer 401 having a thickness of less than several micron and a metal 500 which is a grounding layer.

In addition, resistances 412, capacitors 413, transmission lines 414, inductors 415 are manufactured through a semiconductor manufacturing process on an anodized layer 400 having a thick thickness.

According to another embodiment of the present invention, inter-connection via holes are manufactured using a metal substrate which is a conductor through a thick and selective anodizing process.

FIGS. 4 to 7 are cross-sectional views illustrating a BGA/LGA manufacturing method using inter-connection via holes for surface-mounting on a PCB substrate according to another embodiment of the present invention.

FIG. 4 is a cross-sectional view of attaching and patterning a masking material on a metal substrate. Referring to FIG. 4, a masking material 510 such as SiO₂ or SiNx is attached to a surface of the metal substrate 500 and portions where via holes will be formed is patterned.

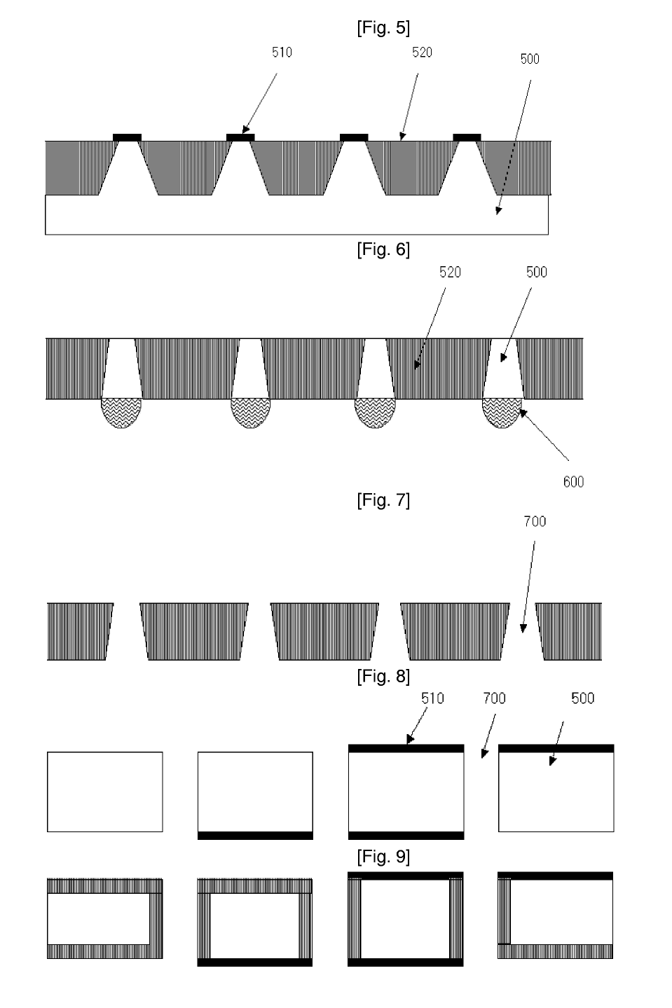

FIG. 5 is a cross-sectional view illustrating a thick metal oxidation layer 520 is formed using an anodizing process.

FIG. 6 is a cross-sectional view illustrating a lower portion of the metal substrate that is not anodized is removed. Referring to FIG. 6, a backside of the metal substrate 500 that is not anodized in FIG. 5 is removed by means of mechanical lapping/polishing or chemical etching until the metal oxidation layer 520 is exposed.

After that, the masking material such as SiO₂ or SiNx used for the selective anodizing is removed and solder bumps 600 are formed in a BGA/LGA type through plating or a silk screen method so that surface-mounting can be performed on a PCB substrate.

Here, if only chemical etching is performed on a relevant portion of the backside of the metal substrate 500 instead of a mechanical lapping/polishing in FIG. 5, a metal oxidation layer having via holes 700 is formed in the relevant portion as illustrated in FIG. 7.

Lastly, if the above-formed via holes 700 are filled with metal, inter-connection via holes are manufactured.

FIGS. 8 to 10 are cross-sectional views illustrating a method for manufacturing inter-connection via holes in a metal substrate according to another embodiment of the present invention.

FIG. 8 is a cross-sectional view explaining a patterning process after forming via holes. Referring to FIG. 8, after the via holes 700 are formed by removing metal of the metal substrate 500 through etching or punching process, a masking material 510 is attached to both sides of the metal substrate 500 and pattering is performed on relevant portions.

FIG. 9 is a cross-sectional view illustrating double-sided, metal oxidation layer manufactured by an anodizing process. Referring to FIG. 9, the anodizing process is performed for prevention of electrical short-circuit reaction in relation to the metal substrate 500 which is a grounding layer and for a signal isolation between the via holes 700.

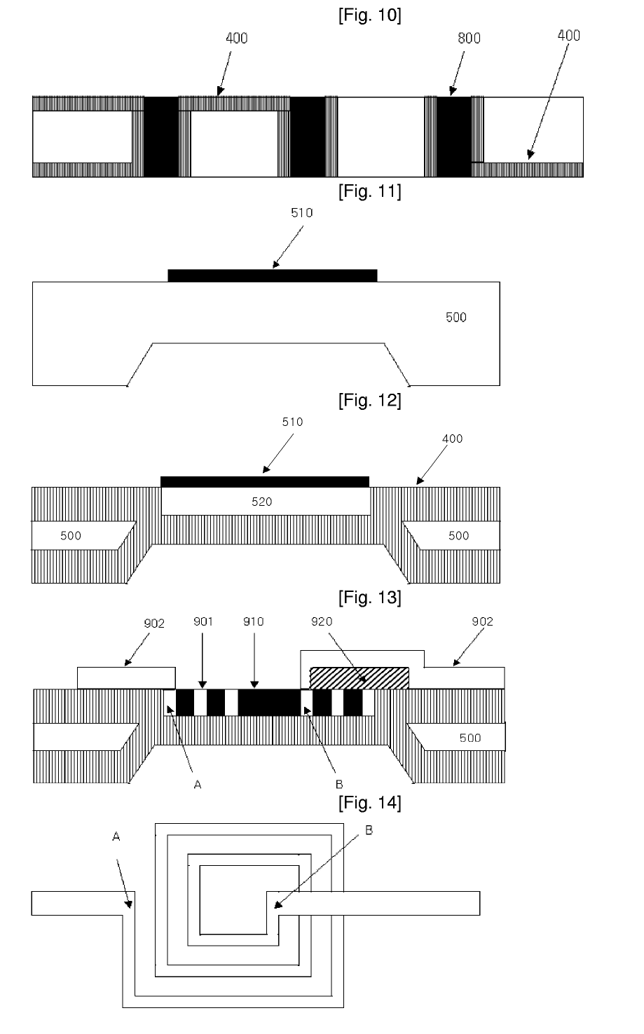

FIG. 10 is a cross-sectional view illustrating that inter-connection via holes are formed. Referring to FIG. 10, if the via holes 700 are filled with metal in a general method after masking material 510 is removed, the inter-connection via holes 800 having a selective, double-sided metal oxidation layer 400 are manufactured.

FIGS. 11 to 13 are cross-sectional views illustrating a method for manufacturing an inductor having a high quality coefficient using a metal substrate and an anodizing process according to still another embodiment of the present invention.

First, for realization of the inductor having a high quality, efforts to reduce parasitic capacitance on a substrate and to reduce a resistance component of an inductor line are required. For that purpose, a thick inductor line is formed through selective etching of a metal substrate formed on a metal oxidation film of a membrane type.

FIG. 11 is a cross-sectional view illustrating etching of a metal substrate in manufacturing an inductor. Referring to FIG. 11, a masking material 510 is attached to a portion on which an inductor will be manufactured and a backside of the metal substrate 500 is etched in a predetermined depth.

FIG. 12 is a cross-sectional view illustrating a metal oxidation layer 400 of the metal substrate 500 is formed. Referring to FIG. 12, the metal oxidation layer 400 is formed through the anodizing process so that a portion 520 on which the inductor will be manufactured may be electrically isolated from other metal portions 500.

FIG. 13 is a cross-sectional view illustrating an upper and a lower lines of the inductor is formed. Referring to FIG. 13, after the masking material 510 is removed, the metal layer 520 that is not anodized is selectively etched to form a lower line 901 of the inductor and, if necessary, an insulating material 910 is attached and an upper line 902 of the inductor is formed.

The lower and the upper lines 901 and 902 of the inductor are connected each other at ‘A’ and ‘B’ and form an insulation layer 920 for electrical insulation.

FIG. 14 is a plan view of an inductor manufactured according to an embodiment of the present invention. Referring to FIG. 14, the upper line 902 is connected with the lower line 901 at the points ‘A’ and ‘B’.

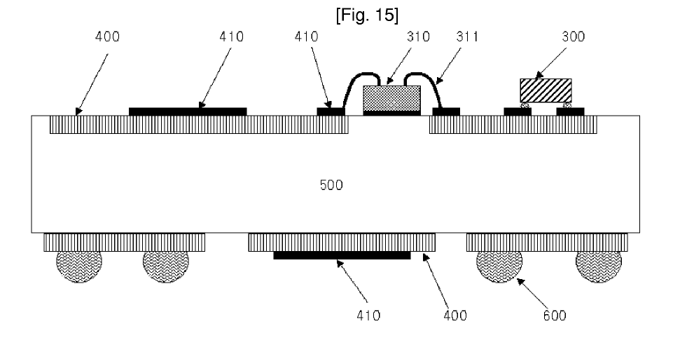

FIG. 15 is a cross-sectional view of a double-sided, metal substrate package manufactured through a package manufacturing process using a selectively anodized metal according to another embodiment of the present invention.

First, a masking material is attached to both sides of the metal substrate 500 and pattering is performed on both the sides and then the anodizing is performed, so that the metal oxidation layer 400 is selectively formed on both the sides of the metal substrate.

The passive elements 410 are formed or semiconductor elements 300 and 310 are attached to the metal oxidation layers 400 respectively formed on both the sides of the metal substrate 500. Not only the passive elements 410 or the semiconductor elements 300 and 310 but also the solder bumps 600 for surface-mounting can be formed.

### INDUSTRIAL APPLICABILITY

While the present invention has been described and illustrated herein with reference to the preferred embodiments thereof, it will be apparent to those skilled in the art that various modifications and variations can be made therein depending on the shapes of the passive elements and the semiconductor elements that will be manufactured on the selectively anodized metal substrate without departing from the spirit and scope of the invention. Thus, it is intended that the present invention covers the modifications and variations of this invention that come within the scope of the appended claims and their equivalents.

What is claimed is:

1. A package using a selectively anodized metal in a semiconductor package for integrating semiconductor elements and passive elements on a metal substrate and protecting these elements using a metal cover, the package being formed by:
a means for integrating the passive elements and the semiconductors on an anodized metal film selectively formed on the metal substrate so as to have a predetermined thickness;
a means for forming bumps through inter-connection via holes for surface-mounting on the anodized metal film of the metal substrate; and
a means for sticking a metal cover for protecting the passive elements and the semiconductor elements integrated on the metal substrate, to the metal substrate.

2. The package of claim 1, wherein the anodized metal film is formed by attaching a thin film to the metal substrate using a masking material and performing an anodizing reaction.

3. The package of claim 1, wherein the passive elements and the semiconductor elements of a bare chip state integrated on the anodized metal film are connected each other using a flip-chip bonding.

4. The package of claim 1, wherein the semiconductor elements integrated on the anodized metal film are fixed to a surface of a metal portion that is not anodized using a thermal conductive adhesive material and connected with the passive elements integrated on the anodized metal film through a wire bonding.

5. The package of claim 1, wherein the metal cover and the selectively anodized metal substrate are connected with each other by an adhesive layer of a conductive epoxy or a metal-to-metal bonding type.

6. A method for manufacturing a package using selectively anodized metal in a semiconductor package manufacturing method for emitting heat generated from semiconductor elements, the method comprising the steps of:
attaching a masking material to a surface of a metal substrate for integrating the semiconductor elements and pattering regions in which via holes will be formed;
selectively anodizing the patterned metal substrate to form a metal oxidation layer having a predetermined thickness;
removing a backside of the metal substrate that is not anodized until the metal oxidation layer is exposed; and
after removing the masking material attached at the pattering step, forming solder bumps for surface-mounting on the metal substrate.

7. The method for manufacturing a package of claim 6, wherein the masking material deposited on the metal substrate at the step of pattering is selected in a group consisting of SiO2, SiNx, and SiO2/SiNx compound.

8. The method for manufacturing a package of claim 6, wherein the step of removing the backside of the metal substrate comprises the step of removing metal through a mechanical lapping/polishing or a chemical etching.

9. The method for manufacturing a package of claim 6, wherein the step of forming the solder bumps comprises the step of forming the solder bumps in a BGA/LGA (ball grid array/land grid array) type through plating or a silk screen method.

10. The method for manufacturing a package of claim 6, further comprising the steps of, in addition to the step of anodizing:
after forming the anodized metal film is completed, forming via holes by removing metal through a chemical etching; and
manufacturing inter-connection via holes by filling via holes with metal.

11. A method for manufacturing a package of claim 6, wherein the package is using selectively anodized metal in a method for forming at least one or more via holes in a metal substrate to connect up and down of the metal substrate each other, the method comprising the steps of:
after attaching a masking material to both sides of the metal substrate in which the via holes are formed, patterning a necessary portion;
anodizing the metal substrate for prevention of electrical short-circuit of the metal substrate and for a signal isolation between the via holes; and
forming inter-connection via holes having a selective, double-sided oxidation layer by filling the via holes with metal.

12. A method for manufacturing a package of claim 11, wherein the package is using selectively anodized metal in a method for manufacturing an inductor reducing parasitic capacitance on a metal substrate and reducing a resistance component of an inductor line, the method comprising the steps of:
attaching a masking material to a portion of the metal substrate where the inductor will be manufactured and etching a backside of the metal substrate in a predetermined depth;
forming an anodized metal film on the metal substrate to electrically isolate the portion where the inductor will be manufactured from other metal portions; and
removing the masking material attached to the metal substrate and selectively etching a metal layer that will not be anodized to form a lower line of the inductor.

13. The method for manufacturing a package of claim 12, further comprising the step of, in addition to the step of removing:
after forming the lower line of the inductor is completed, attaching an insulating material and then forming an upper line of the inductor.

14. A method for manufacturing a package of claim 11, wherein the package is using selectively anodized metal in a method for manufacturing a metal substrate integrating semiconductor elements and passive elements thereon, the method comprising the steps of:
attaching a masking material on both sides of the metal substrate and patterning both the sides; and
forming a metal oxidation layer by selectively anodizing both the sides of the metal substrate.

15. The method for manufacturing a package of claim 14, further comprising the step of:
attaching the passive elements or the semiconductor elements to both sides of the metal substrate on which the metal oxidation layer is formed at the step of forming the metal oxidation layer.

16. The method for manufacturing a package of claim 14, further comprising the step of:
forming solder bumps for surface-mounting on both the sides of the metal substrate on which the metal oxidation layer is formed at the step of forming the metal oxidation layer.
